(19) United States
(12) Patent Application Publication
(10) Pub. No.: US 2001/0014268 A1
(43) Pub. Date: Aug. 16, 2001

(54) MULTI-AXIS TRANSFER ARM WITH AN EXTENSIBLE TRACKED CARRIAGE

(76) Inventors: CHARLES S. BRYSON III, SANTA CLARA, CA (US); MICHAEL A. ACKERET, SAN JOSE, CA (US); XIAO-ZHONG (JAMES) WU, FREMONT, CA (US); JIBING ZENG, FREMONT, CA (US)

Correspondence Address: LAW OFFICES OF CHARLES GUENZER, P O BOX 60729, PALO ALTO, CA, 94306

(21) Appl. No.: 09/181,794

(22) Filed: Oct. 28, 1998

(51) Int. Cl. B65G 17/08; C23C 16/00

(52) U.S. Cl. 414/217; 118/719

(57) ABSTRACT

A transfer arm assembly for transferring wafers between a load-lock chamber or a transfer chamber and processing chamber. The wafer is selectively held on the end of a paddle. Linear horizontal motion is provided by a drawer-slide mechanism including a base, a carriage, and the paddle. Slides are mounted on the base and on the carriage. Wheels mounted on the carriage slidably engage the base slides and support the carriage on the base, and wheels mounted on the paddle slidably engage the carriage slides and support the paddle on the carriage. Thereby, the paddle may be projected a distance greater than the lateral extent of the base or of the vacuum chamber accommodating the base and its supported components in their retracted positions. A single motor mounted on the carriage can provide the two relative motions among the base, carriage, and paddle by means of two belt mechanisms wrapped around two capstans attached to the motor shaft. Additional degrees of motion are provided by a rotating turntable and by a lifting four-bar mechanism or cam follower.

### FIELD OF THE INVENTION

The invention relates generally to single-substrate handling systems. In particular, the invention relates to transfer arm assemblies usable in vacuum processing systems.

### BACKGROUND ART

Many of the steps required for the fabrication of semiconductor integrated circuits and related products such as flat-panel display screens rely upon vacuum processing of the substrates. Such steps include chemical vapor deposition (CVD), sputtering or physical vapor deposition (PVD), and dry etching. Sputtering and dry etching almost always rely upon the generation of a plasma in the processing chamber, and many types of CVD are plasma-enhanced. In all these cases, the processing is performed while the interior of the processing chamber is maintained at a strong vacuum, in the range of 1 Torr to less than 10⁻⁶ Torr.

To use the chamber to process a semiconductor wafer, it is possible to sequentially open the vacuum chamber, transfer the wafer from the ambient into the chamber for processing, close the chamber and pump it down, and thereafter process the wafer in the chamber. However, such a method suffers at least two major problems. First, throughput is severely reduced in a production environment by the requirement to pump the chamber down from atmospheric pressure to low pressure for each wafer or even batch of wafers contained in a boat. Secondly, opening the chamber to the ambient atmosphere exposes it to air borne contaminants which can settle on the walls of the vacuum chamber and eventually onto the wafer. Furthermore, in many cases it is desired to transfer a wafer from one processing step to the next without exposing the wafer to the oxidizing ambient. An example of such a sequence includes a plasma pre-clean before a sputtering step.

For these reasons, much of front-end semiconductor processing is done in cluster tools, which are assemblages of processing chambers interconnected through a vacuum transfer chamber. An exemplary cluster tool designed for use in a production environment is illustrated schematically in FIG. 1 and resembles that disclosed by Maher et al. in U.S. Pat. No. 4,715,921, incorporated herein by reference in its entirety. Multiple vacuum processing chambers 10 and a load-lock chamber 12 are arranged around the periphery of a central transfer chamber 14. Two load-lock chambers 12 may be used in order to allow continuous operation during cassette changing or to allow the wafers to be output to a different cassette than that used to input them. Gate valves 16 selectively isolate the transfer chamber 14 from the processing chambers 10 and the load-lock chamber 12. The load-lock chamber 12 is used to transfer wafers into and out of the system. It includes a vacuum sealable door 18 which may be opened to allow an operator to insert or remove wafers to and from the load-lock chamber 12, during which the load-lock chamber 12 is at atmospheric pressure. In a production environment, the wafers are horizontally loaded into a cassette, and the operator loads and unloads the cassette as a whole. Typically, a wall 20 is sealed to the sides of the load-lock chamber 12 and defines the boundary between the clean room in which the operator works in transferring wafers and a less clean mechanical area containing the support equipment for the cluster tools but which faces only the sealed exterior of the processing chambers 10 and transfer chamber 14.

A transfer arm assembly 22 is operated from within the transfer chamber 14 and includes a transfer paddle 24 for supporting a wafer 26 being transferred. Conventionally, the transfer arm assembly 22 is mounted on a central shaft 28 and includes rotation and extension means between the shaft 28 and the wafer paddle 24. The rotation means allows the paddle 24 to be positioned facing a selected one of the load-lock chamber 12 and any of the processing chambers 10. The extension means allows the paddle 24 to insert the wafer 26 through the opened associated gate valve 16 and into or out of either the load-lock chamber 12 or the processing chambers 10, at which point unillustrated but conventional apparatus effect the wafer transfer between the paddle and the processing chamber 10 or load-lock chamber 12. After the transfer, the paddle 24 is withdrawn and the gate valve 16 is closed.

Typically, the load-lock chamber 12, the transfer chamber 14, and each of the processing chambers 10 have their separately controlled, vacuum pumping systems connected to pumping ports 29 on the processing chambers 10 and an unillustrated ports on the load-lock chamber 12 and the transfer chamber 14. After the operator has loaded the cassette into the load-lock chamber 12 through the clean-room door 18, the door 18 is closed and the vacuum system pumps the load-lock chamber 12 down to a pressure associated with the transfer chamber 14, which may be 1 Torr for CVD, but in a more complex arrangement than that illustrated may be 10⁻⁶ Torr for PVD. The gate valve 16 between the load-lock chamber 12 is then opened to allow the transfer arm assembly 22 to withdraw a wafer 26 from the load-lock chamber 12, rotate with it to a selected processing chamber 10, and insert the wafer 26 through an opened gate valve 16 into the selected processing chamber 10. The gate valve 16 associated with the selected chamber 10 is then closed, further vacuum pumping is performed if necessary, and the wafer 26 is then processed in an environment isolated from the transfer chamber 14. After the processing in one chamber is completed, the transfer arm assembly 22 may transfer the wafer 26 to another chamber for further processing or may transfer it back to the load-lock chamber 12. After all wafers have been processed and returned to the cassette in the load-lock chamber 18, the load-lock gate valve 16 is closed, and the operator can remove the cassette through the door 18.

During the entire time, the transfer chamber 14 and the processing chambers 10 have remained at vacuum so that only a short pump down is required and contaminants are excluded. With a cluster tool, a long pump down and bake out may be performed once in an initialization period after the system has been closed up after maintenance or the like, and thereafter the system except for the load-lock chamber 18 remains clean and at vacuum.

There are two principal types of extension means allowing the relatively long throw of the wafer paddle 24 from the transfer chamber 14 into the processing chamber 10 or load-lock chamber 18. The schematically illustrated mechanism is a frog-leg assembly of two parallel two-section legs. If the shaft 28 contains two concentric shafts, each driving one of the legs, controlled rotation of the two shafts effects both the desired rotation and extension. A simpler version of the extension and rotation means is a dog-leg assembly with a single leg having a rotatable mid joint and having its inner leg mounted on a rotatable shaft. The throw of a frog-leg or dog-leg assembly is limited to about half the diameter of the transfer chamber 14, thus imposing constraints upon the designs of the transfer chamber 14, the load-lock chamber 12 and its cassette, and the processing chambers 10.

The sizes of semiconductor wafers is significantly increasing with a large effort being pursued to switch from 200 mm wafers to 300 mm ones. Some systems for processing flat-panels use a cluster tool with very similar parts. The sizes of glass substrates are already very large, e.g., 450 mm×600 mm, and the size will increase in future tools. Furthermore, these glass substrates are relatively thick and heavy. Both the frog leg and the dog leg, when applied to the larger substrates, suffer from being supported on a rotatable central shaft. Such a shaft cannot be made rigid, particularly when supported only on one end, and the bearings introduce some play. Assuming a 2 cm shaft, any such movement is multiplied by a factor of 15 for a 300 mm wafer. Vertical uncertainties of up to a centimeter need to be considered, and designs to accommodate such large uncertain motion will be expensive.

For laboratory applications and for some low-production applications, it is often not necessary to use the large cluster tool of FIG. 1. A one-chamber system is illustrated in schematic plan view in FIG. 2. One processing chamber 10 is connected through a gate valve 16 to a load-lock chamber 14. In one embodiment particularly applicable to a laboratory, the load-lock chamber 14 has a vacuum sealable door 30 through which the operator can transfer a wafer at a time to and from a paddle 32 connected to a shaft 34. A slidable vacuum seal 36 passes the paddle shaft 34 and allows the operator to move the paddle 32 and attached wafer 26 through the gate valve 16 into and out of the processing chamber 10. In a low-volume production environment, the load-lock chamber 14 can be adapted to receive a wafer cassette, and the paddle 21 and attached shaft 34 operate through the cassette.

Although the one-chamber system of FIG. 2 is simple, it suffers the disadvantage of a large footprint. The area occupied by the shaft 34 in its externally extended position occupies extremely valuable clean room space in a very non-square configuration. The footprint problem is determined by the throw of the paddle 32 being limited to the external extension of the shaft 34.

The two described transfer arm assemblies provide up to two degrees of freedom of motion. The transfer arm in cluster tool needs two axes of motion, rotation and extension. The arm with the single processing chamber has been described has having only one axis, that of extension, but it is relatively easy to provide an axial rotation to the shaft. Nonetheless, additional motive axes are desired, such as vertical motion or tilting for the cluster tool. For example, in the cluster tool, the transfer between the wafer paddle and the processing chamber or the load-lock chamber is usually effected by movement of the support pedestal in each of the processing chambers and the movement of the cassette in the load-lock chamber. It would be desirable to achieve the transfer with a single vertical actuator in the transfer arm assembly. Although such mechanical designs are available, in combination with the described transfer arm assemblies, they tend to be very complex because of the need to penetrate the vacuum wall and to remain in registry with the existing motions. Generally, motors and actuators used for the movement inside a vacuum chamber are mechanically powered from outside the vacuum chamber with mechanical vacuum feed throughs used to penetrate the vacuum wall.

### SUMMARY OF THE INVENTION

The invention may be summarized as a transfer assembly including features for a long throw, for reduced jitter, for simplified chamber penetration of power needed in the transfer, and for multi-axis movement.

A linearly moving transfer arm assembly includes a multi-stage tracked mechanism, such as a drawer-slide mechanism including a base, a carriage, and a paddle arm assembly with the paddle arm assembly being capable of supporting a substrate on an end thereof. Pulleys and tracks provide for support and sliding motion between the base and the carriage and between the carriage and the paddle arm assembly so that the transfer arm assembly can be retracted to within a load-lock chamber or transfer chamber or can be projected through a gate valve between the chamber and a processing chamber.

One motor mounted on the carriage can be used to provide both relative motions with two mechanical means coupled between the motor shaft and the base and transfer arm assembly respectively.

Additional degrees are motion are easily obtained. For one example, a turntable, which may be powered by a motor inside the vacuum chamber, supports the base. For another example, vertical motion may be provided by interposing a vertically moving mechanism between the chamber wall and the base.

### BRIEF DESCRIPTION OF THE DRAWINGS

FIG. 1 is a schematic plan view of a multi-chamber cluster tool.

FIG. 2 is a schematic plan view of a single-chamber load-lock chamber.

FIG. 3 is an orthographic view of a transfer arm assembly using a drawer-slide mechanism.

FIG. 4 is a top view of a linear actuator used with the transfer arm assembly of FIG. 3.

FIG. 5 is an orthographic view of a load-lock chamber enclosing the transfer arm assembly of FIG. 3.

FIG. 6 is a cross-sectional view of an alternative tracked mechanism utilizing a rod slide.

FIG. 7 is a schematic elevational view of the load-lock chamber of FIG. 5 additionally including a turntable.

FIG. 7 is a schematic plan view of a load-lock chamber coupled to two processing chambers.

FIG. 8 is an elevational view of a four-bar mechanism which may additionally be incorporated into a load-lock or transfer chamber to provide vertical motion.

FIG. 9 is an elevational view of a cam follower which may additionally be incorporated into a load-lock or transfer chamber for a similar purpose.

### DETAILED DESCRIPTION OF THE PREFERRED EMBODIMENTS

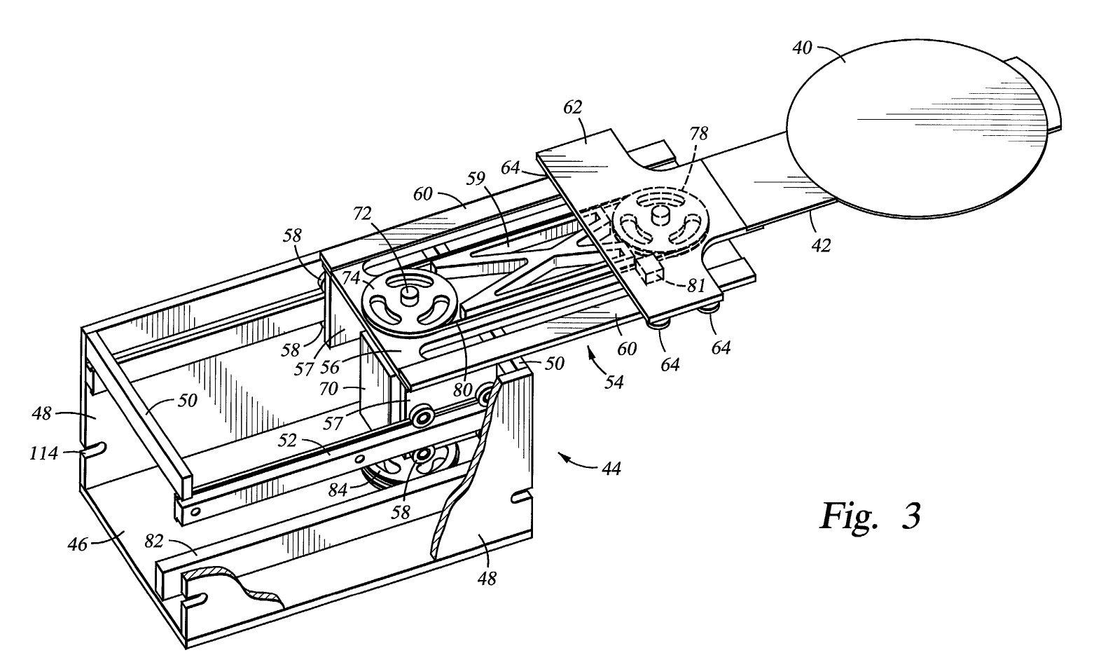

One embodiment of the invention, as illustrated in the orthographic view of FIG. 3, provides for the longitudinal movement of a substrate 40 supported on a paddle 42 by linear compound tracked movement with respect to a base 44. Included in the base 44 are a base plate 46, two side plates 48, and two cross stiffeners 50. The two side plates 48 support two parallel horizontally extending base tracks 52. A carriage 54 includes a carriage plate 56 and two carriage legs 57 attached to a proximal end of the carriage plate 56. By proximal is meant the end with respect to the linear axis of motion opposite the end of the assembly from which the substrate is projected. That end is the distal end. Each carriage leg 57 freely and rotatably supports multiple wheels 58 that engage opposing sides of the respective tracks 52 so that the tracks 52 and base 44 freely and linearly support the carriage 54. Stiffening ribs 59 allow the carriage plate 56 to be fairly thin and light. The base tracks 52 are separated by a distance greater than 80% of the diameter of the substrate 40 so that roll jitter is significantly reduced.

Attached to the carriage plate 56 are two parallel, horizontally extending carriage tracks 60. A paddle base 62 positioned above the carriage plate 56 includes on each of its two lateral sides multiple free-wheeling wheels 64 that engage opposing sides of the respective tracks 60. As a result, the paddle base 62 slides linearly on the carriage 54. The paddle 42 is attached to the distal end of the paddle base 62. The exact form of the paddle 42 may be freely chosen and may include recesses, arms, spider legs, or an electrostatic chuck.

The carriage tracks 60 are illustrated as being engaged on horizontal sides by the paddle wheels 64, but a vertical or other orientation is also possible. A symmetric design includes four wheels 58 or 64 at each sliding engagement point with the track 52 or 64. Three triangularly arranged wheels would suffice, and only two are possible if properly positioned to support the projected weight. The concept of a rolling slide mechanism is broader than the specific embodiment described above. The wheels may have flat or concavely or convexly shaped circumferences as long they are constrained to follow the corresponding rails. The embodiments show opposed wheels contacting two opposed outside surfaces of a rail. However, it is possible to arrange the track to have an internal linearly extending cavity and to place wheels inside the cavity to engage opposed inner surfaces of the track. Wheels include other cylindrically symmetric members such as rollers with an axle and further include spherical members captured in bearing cages, all of which roll in or on and are captured by tracks.

The resulting motion of the paddle 42, carriage 54, and base 44 resemble the motion of a set of side draw slides that allow the full extent of a drawer to project beyond a cabinet.

A motor 70 is supported at the bottom of the proximal end of the carriage plate 56, preferably by side mounts to one of the carriage legs. An example of the motor 70 is a high-vacuum compatible stepper motor, such as Arun Microelectronics Ltd. (AML) Model B23.2 available through Surface/Interface, Inc. of Sunnyvale, Calif. The motor 70 includes a vertical shaft 72 penetrating the carriage plate 56 and engaged to a capstan 74. An idler pulley 78 is symmetrically placed with respect to the capstan 74 and is freely rotatably supported on the distal end of the carriage plate 64. A stainless steel belt 80 is wrapped around the capstan 74 and the idler pulley 78 and is fixed at a point 81 to the bottom of the paddle base 62. Thereby, rotation of the motor 70 in one direction or the other will result in the linear projection or retraction of the paddle 42 and attached wafer 40 with respect to the carriage 54 as the paddle base 62 is controlled to slide along the tracks 60. Tension means may be included with the belt 80 or idler pulley 78 to promote engagement of the belt 80 with the capstan 74 and to ease its installation.

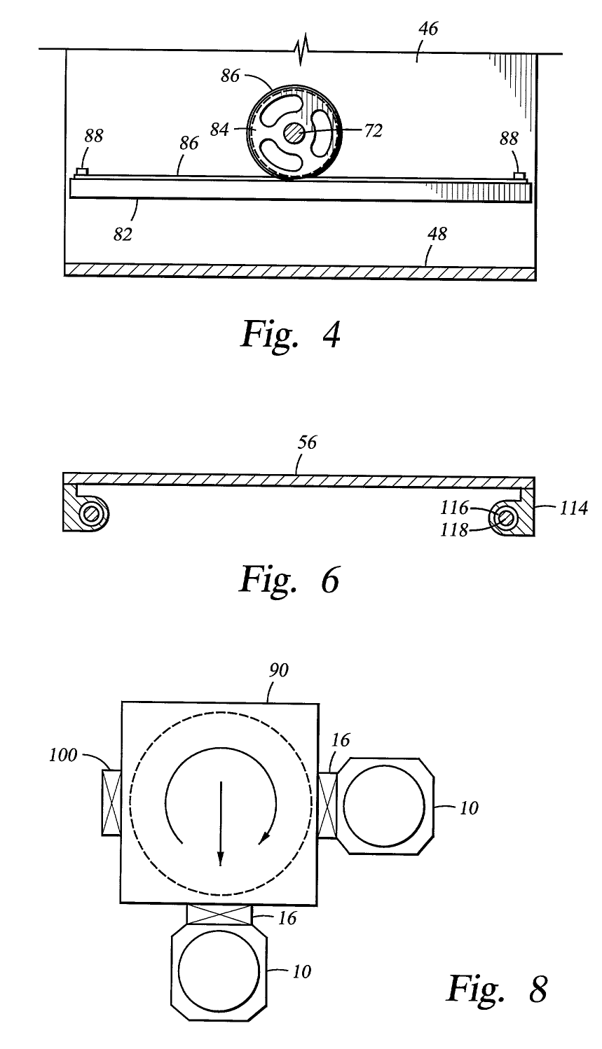

The movement of the carriage 54 with respect to the base 44 is controlled by the mechanism illustrated schematically in plan view in FIG. 4 that is related to a rack-and-pinion drive. A rack rib 82, also illustrated partially in FIG. 3, is attached to the base plate 46 and extends along the direction of travel of the carriage 54. The shaft 72 of the motor 70, which is attached to the carriage 54, is attached to a second capstan 84. A second stainless steel belt 86 is wrapped around the capstan 84 and has its two ends attached by screws 88 to the proximal and distal ends of the rack rib 82. Various means may be used to account for the required pitch of the belt 86 on the capstan 84 to avoid scraping of the belt edges against each other including elevating the attachment of one end of the rack rib 82 with respect to that at the other end. Thereby, when the motor shaft 72 rotates, the shaft 72 and attached carriage 54 move linearly with respect to the base 44. The orientations are arranged such that, when the single shaft 72 rotates in one direction, both the carriage 54 is projected from the base 44 and the paddle 42 is projected from the carriage 54, and, when the shaft 72 rotates in the opposite direction, both the carriage 54 and the paddle 42 are retracted.

The base 44 and attached mechanism are attached to the inside bottom of a load-lock chamber 90 illustrated orthographically in FIG. 5, which is connected via a schematically illustrated pumping port 91 and unillustrated pumping line to an independent vacuum pumping system. The load-lock chamber 90 includes a main chamber wall 92 and a removable top wall 94 with a viewing port 96. A distal projection 98 of the chamber wall 90 is sealably connected to a gate valve 16 of the processing chamber 10 of FIG. 2. An unillustrated aperture in the distal projection 98 is aligned with the aperture of the gate valve 16 and allows the carriage plate 56 to project partially through the load-lock aperture and the paddle 42 and paddle base 62 to completely project.

The load-lock chamber 90 further includes an ingress door 100 rotatably supported on hinges 102 so that it can be opened to allow the transfer of a wafer into the load-lock chamber 90 (while the gate valve 16 is closed) and so that it can be closed and sealed to the chamber wall 92 with an O-ring inserted in a groove 104. A door latch 106 and latch plate 108 can be latched after insertion of the wafer and before the pump down of the load-lock chamber 90 to insure sealing of the door. The carriage 54 and paddle 42 are in their retracted positions when the load-lock door 100 is opened.

Once the operator or other mechanism inserts the wafer into the load-lock chamber 90, the chamber 90 is pumped down to approximately the pressure of the processing chamber 10. Thereafter, the gate valve 16 is opened, and the motor 70 is rotated to project the carriage 56 and the paddle 42 into the processing chamber 10. In most applications, the wafer 40 is transferred from the paddle 42 to an unillustrated pedestal in the processing chamber 10. Thereafter, the motor 70 rotates in the opposite direction to retract the carriage 56 and paddle 42 back into the load-lock chamber 90, and the gate valve 16 closes to allow processing of the wafer 40 without contaminating the load-lock chamber 90. The removal of the wafer from the processing chamber 10 follows the same operation in reverse. Importantly, the gate valve 16 is closed before the load-lock door 100 is opened.

The chamber wall 92 includes one or more standard electrical interface ports 110 to which can be attached vacuum feed through that allow for the introduction of electrical lines into the vacuum chamber 90. Some of these lines are included in an electrical cable controlling the motor 70 controlling the projection and retraction of the transfer arm. The motor cable needs to be partially confined within the chamber 90 to a cable channel so as not to foul the movement of the carriage 54. Unused interface ports 110 are plugged. An optical sensor 112 attached to the chamber wall 92 and projecting through slits 114 in the base side plate 48 (FIG. 3) is used to establish the end-point travel of the carriage 54 for initial calibration of the motor 70 and to assure that the motor has not lost calibration.

The exact form of the load-lock chamber may be freely adapted. An alternate design includes a hinged top wall, perhaps including the area of the side door 100, so as to allow the operator to freely access the chamber interior to place a wafer directly on the paddle 42.

It should be appreciated that the sliding engagement provided by wheels and tracks between the carriage and the base can be accomplished with the wheels being disposed on the base and the tracks being disposed on the carriage. The same comment can be made about the wheels and tracks between the paddle base and the carriage. It is also possible that each of the supporting and supported members includes one wheel and one track on each of their sides such that each wheel axled to one member engages the track of the other member.

An alternative tracked mechanism not utilizing wheels is a rod-slide mechanism illustrated in cross section in FIG. 6 coupling the carriage 54 and the base 44. The bottom plate 56 of the carriage 54 is fixed to and supported by at least two legs 114. Polymeric bushings 116 fixed in the legs 114 closely but slidably capture track rods 118 which are fixed at their ends to proximal and distal ends of the base 44. The bushings 116 and rods 118 act as linear bearings providing sliding support for the carriage 54. The lengths of the bushings 116 can be substantially reduced, thus reducing pump down time, by including two sets of vertically offset rods 116 engaging two sets of bushings 116 and carriage legs 114. The bushings 116 are preferably horizontally somewhat offset to increase the cantilever support but not by an amount which would unduly reduce the throw. The same mechanism may be applied to the coupling between the paddle 42 and the carriage 54.

The design of the drawer-slide transfer arm has several advantages. It allows a throw that substantially equals the linear extent of the transfer chamber, here the load lock chamber. The paddle is supported by side rails positioned near the chamber wall at or slightly beyond the diameter of the wafer. Thereby, paddle jitter is substantially reduced. The use of an interior motor rather than a motor exterior to the chamber significantly reduces the complexity of vacuum penetration from a rotatable vacuum seal of a shaft subject to yaw to a passive electrical feed through.

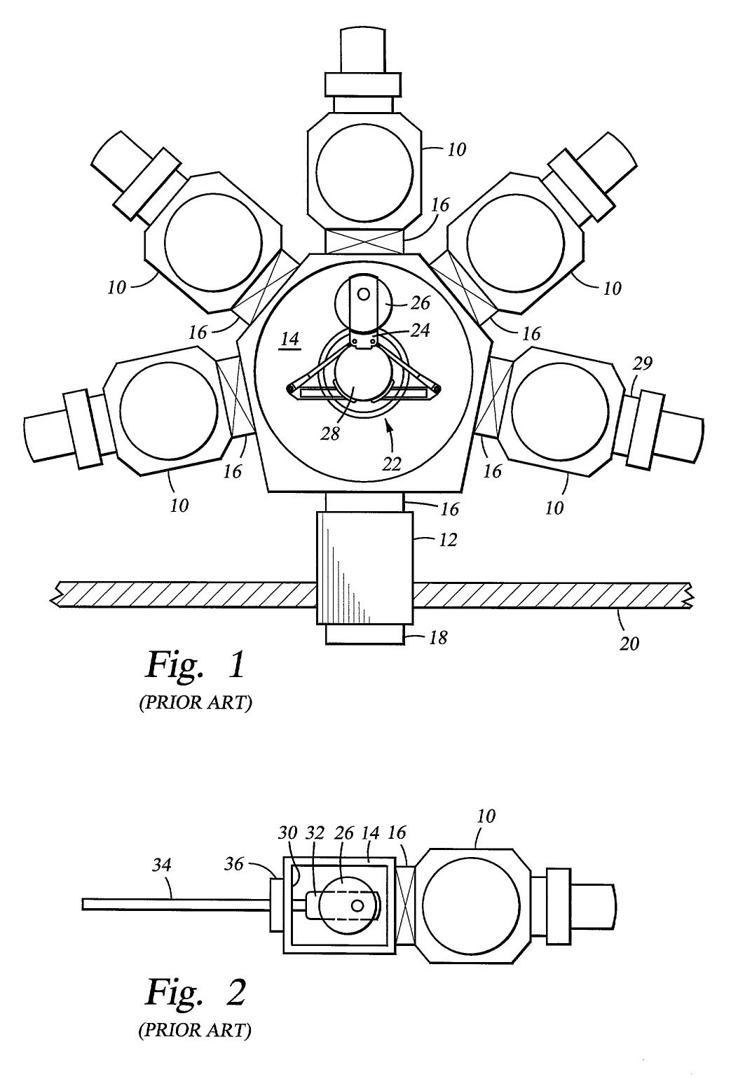

Once the mechanism for linear projection has been freed from the chamber walls, the mechanisms for multi-axis transfer arm assemblies can be substantially simplified. The drawer-slide mechanism of FIG. 3 provides R motion within the geometry of the cluster tool of FIG. 1. If multiple processing chambers are to be used, it is greatly desired to provide R-Θ motion.

A mechanism for providing R-Θ motion is illustrated schematically in cross section in FIG. 7. The base 44 contains the previously described drawer-slide mechanism 120 including the base track 52, the carriage 54 including the wheels 58 gripping the base track 52, the paddle 42 including the wheels 64 gripping the track of the carriage 54, and the wafer 40 supportable on the paddle 42. The base 44 is supported and fixed to a carousel or turntable 122 fixed to a central drive shaft 124 of a motor 126 fixed to the bottom of the load-lock chamber wall 92. The turntable motor 126 is powered and controlled by electrical lines 128 connected to respective lines in an electrical feed 120 sealed to one of the standard interface ports 110.

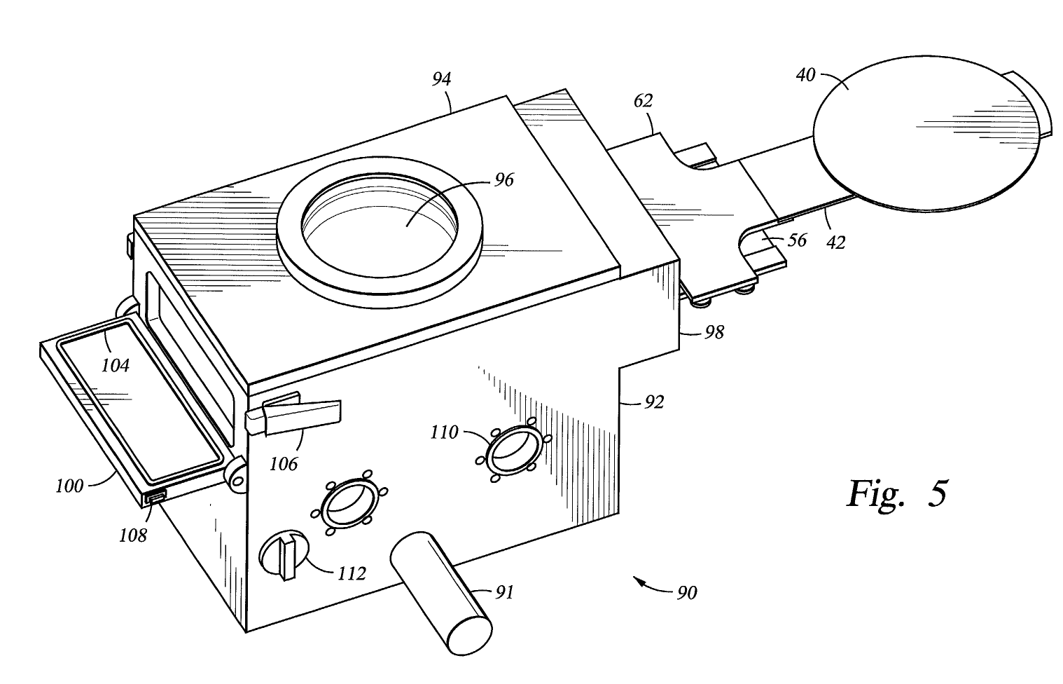

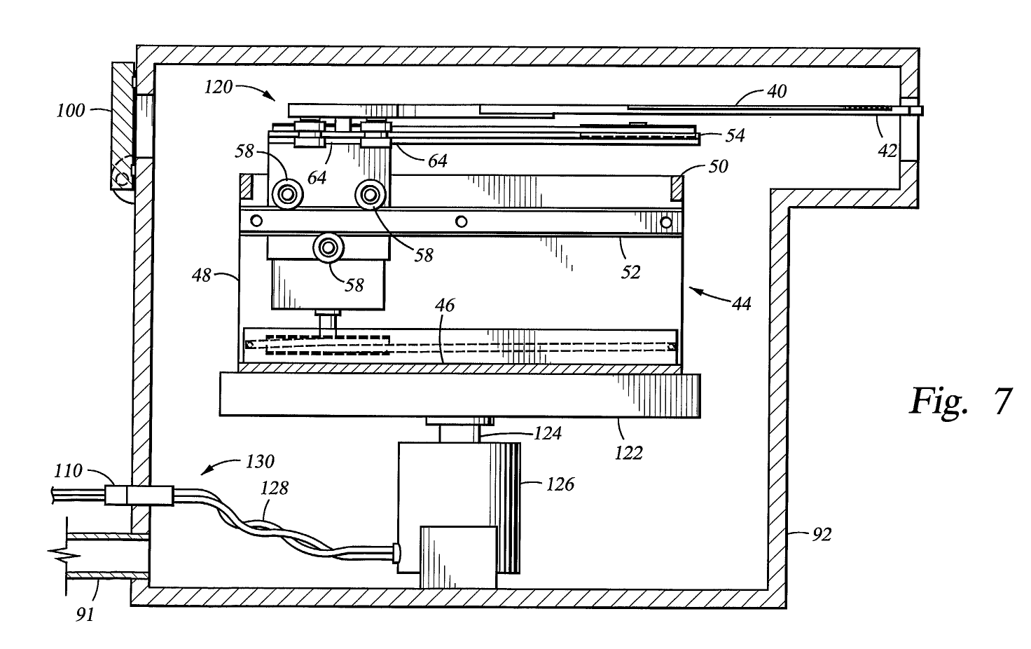

The interior turntable motor 126 provides Θ motion to the base 44 already providing R motion. As a result, the illustrate mechanism is fully capable of providing the R-Θ motion required for the cluster tool of FIG. 1. A simplified cluster tool benefitting from the R-Θ motion is a two-chamber, singly loaded system illustrated in FIG. 8. Two processing chamber 10 are connected through respective gate valves 16 to different angularly located walls of the load-lock chamber 90, and wafers can be loaded into the load-lock chamber 90 through its door 100. The load-lock chamber 90 includes the R-Θ mechanism illustrated in FIG. 7, thereby providing not only for insertion of the wafer through the load-lock door 100, but also selection of which processing chamber 10 will be accessed. Furthermore, it allows a wafer to be inserted into the load-lock chamber 90 through the load-lock door 100, processed first in one of the processing chambers 10 and then in the other processing chamber 10 before being retrieved through the load-lock door 100. An example of the application of this two-chamber system is the plasma preclean prior to a sputter deposition without the intermediate exposure of the wafer to atmosphere. Other, more complicated processes may include more than two processing chambers associated with the load-lock chamber 90.

In the configuration of FIG. 7, an additional bearing or other tracked interface between the top of the load-lock chamber 90 and the top of the base 44 may be used to provide additional rigidity to the base 44. If desired, the motor 126 can be placed outside of the vacuum chamber 90 with its shaft penetrating a rotary seal, as is conventional in prior-art transfer chambers, but the illustrated interior motor 126 eliminates the troublesome and expensive mechanical vacuum seal.

It is desired to also provide some Z motion to the transfer arm assembly. Especially, a vertical motion of 1 cm or less would allow the transfer of the wafer between the paddle and the pedestal within the processing chamber or separate load-lock chamber without any motion of the pedestal or cassette. There are a number of ways of providing the desired Z motion that are easily combinable with the tracked mechanisms described above.

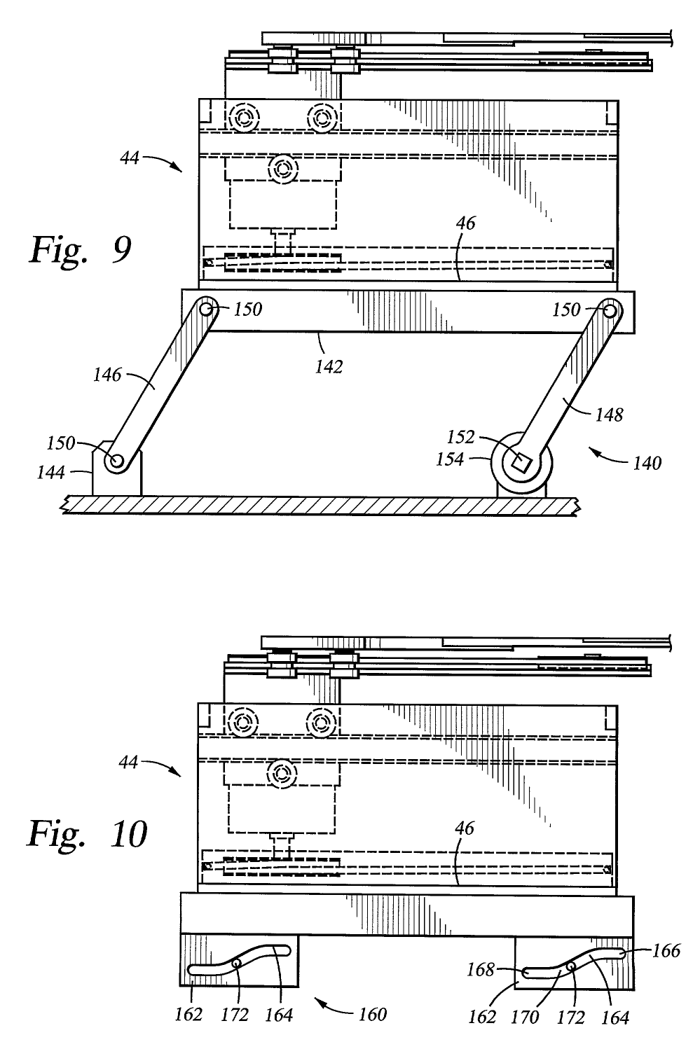

A first Z-axis lift mechanism is a four-bar mechanism 140 illustrated schematically in the side view of FIG. 9. The four-bar mechanism 140 includes a top bar 142, two bottom supports 144 arranged in parallel with the top bar, and parallel side bars 146, 148 coupled to each other in a parallelogram shape by three pivoting joints 150 and one motor shaft 152 driven by a motor 154. The bottom supports 144 and the motor body 154 are fixed to either the bottom of the load-lock chamber wall 92 or to the turntable 122 depending upon whether rotary motion is required as well as radial and vertical motions. The base plate 46 of the base 44 of FIG. 3 is connected to the top of the top bar 142 preferably with the direction of projection and retraction of the paddle 42 aligned in the plane of rotation of the side bars 146, 148. The motor shaft 152 is fixed to the right side bar 148 inside the vacuum chamber 90. When it rotates, it causes the right side bar 148 to rotate and thus to raise or lower the top bar 142 and hence the base 44 and attached paddle 42.

Another Z-axis lift mechanism is a cam follower 160 illustrated schematically in the side view of FIG. 10. Four guide plates 162 (only two are illustrated) are fixed to the bottom of the base plate 46 of the base 44 at its four corners. The guide plates 162 include similarly shaped and oriented curved cam guide slots 164 having horizontal upper and lower portions 166, 168 vertically displaced from each other and smoothly joined by an inclined portion 170. A pin or roller 172 slides in and is guided by each of guide slots 164. Each of the four pins 172 is fixed to either the side of the chamber wall 92 or to upward projections from the turntable 122. A horizontal linear actuator such as the belt-type rack and pinion of FIG. 4 is connected to either the base plate 46 or guide plates 162 to cause them to move laterally in the illustration relative to the pins 172. Sufficient lateral movement causes a vertical displacement of the base plate 46 and attached paddle 42 by an amount equal to the vertical displacement of the two horizontal portions 166, 168 of the guide slot 164.

Other vertically moving mechanisms are possible, such as a worm mechanism including four vertical guides passing through the base plate 46, a vertically arranged worm gear engaged to a worm box in the base plate, and a motor fixed to the bottom of the chamber wall 90 or turntable 112 turning the worm gear.

Yet further degrees of freedom can be envisioned, such as a roll tilt or a pitch tilt of the paddle. With the projection detached from the walls of the chamber and particularly with the use of interior motors, these additional mechanisms can be placed.

Although the examples of the transfer arm assembly have been described above in context of being disposed within a load-lock chamber, they may be equally applied to cluster tools with the assembly being disposed inside the transfer chamber with access to not only the processing chambers but also to the load-lock chamber.

The invention thus provides simple but rugged mechanisms that reduce the need for mechanical penetration of the vacuum chamber walls.

What is claimed is:

1. A transfer arm assembly adapted for use in a vacuum chamber having at least chamber aperture selectively sealable by a gate valve, comprising:
a base;
a carriage;
a first tracked mechanism interposed between said base and said carriage to provide sliding support of said carriage on said base;
a paddle assembly for supporting a substrate on a distal portion thereof;
a second tracked mechanism interposed between said paddle assembly and said carriage to provide sliding support of said carriage on said base; and
a motor fixed to said carriage and having coupling members linked to said base and to said paddle assembly to provide simultaneous linear motion along said first direction between said base and carriage and between said carriage and said paddle assembly and enabling said paddle assembly to be confined within said vacuum chamber when said gate valve is closed and to project said distal of said through said gate valve when it is opened.

2. The transfer arm assembly of claim 1
wherein said first tracked mechanism includes two first tracks fixed to either said base or said carriage and extending in a first direction and a plurality of first wheels rotatably fixed to either of said base or said carriage and rollably engaging said first tracks for slidably supporting said carriage on said base, and
wherein said second tracked mechanism includes two second tracks fixed to either said carriage or said paddle assembly and extending in said first direction and a plurality of second wheels rotatably fixed to either said carriage or said paddle assembly and rollably engaging said second tracks for slidably supporting said paddle assembly on said carriage.

3. The transfer arm assembly of claim 2, wherein said two first tracks are fixed to one of said carriage and said base and said second wheels are rotatably fixed to the other of said base and said carriage and wherein said two second tracks are fixed on one of said paddle assembly and said carriage and said second wheels are rotatably fixed to the other of said paddle assembly and said carriage.

4. The transfer arm assembly of claim 1, wherein at least one of said first and second tracked mechanisms include linear bearings and rods slidably captured in said linear bearings.

5. The transfer arm assembly of claim 1, wherein said coupling members include a first and a second capstan fixed to a shaft of said motor, a first belt at least partially wrapped around said first capstan and being fixed in a least one position to said base, and a second belt at least partially wrapped around said second capstan and fixed in at least one position to said paddle assembly.

6. The transfer arm assembly of claim 5, wherein said first belt is fixed at two ends thereof to said base and wherein said second belt is continuous and wrapped around a pulley supported on said carriage.

7. The transfer arm assembly of claim 1, further comprising a turntable rotatably disposable in chamber to support said base.

8. The transfer arm assembly of claim 7, further comprising a motor disposed in said chamber and rotating said turntable.

9. The transfer arm assembly of claim 1, further comprising a vertically moving mechanism disposable in said chamber to support said base.

10. A vacuum processing system, comprising:
a central chamber;
at least one processing chamber in selective communication with said central chamber through a selectively closable gate;
a base disposed in said central chamber;
a carriage slidably supported on said base through a first tracked mechanism; and
an arm capable of bearing a substrate thereon and slidably supported on said carriage through a second tracked mechanism;
whereby said arm is retractable into said central chamber and can be projected through said gate valve into said processing chamber when said gate valve is opened.

11. The vacuum processing system of claim 10, wherein said first tracked mechanism includes at least two first tracks and a plurality of first wheels engaging said first tracks and wherein said second tracked mechanism includes two second tracks and a plurality of second wheels engaging said second tracks.

12. The vacuum processing system of claim 10, further comprising a motor supported on said carriage and powering a first mechanical system linking said base and said carriage and a second mechanical system linking said carriage and said arm to provide relative linear motion between said base, said carriage, and said arm.

13. The vacuum processing system of claim 10, wherein said central chamber and said processing chamber are independently vacuum pumped.

14. The vacuum processing system of claim 10, wherein said system comprises a plurality of said processing chambers all of which are accessible by said arm.

15. The vacuum processing system of claim 14, wherein said system further comprises a load-lock chamber in selective communication with said central chamber through a selectively closable gate for accommodating therein a cassette capable of holding a plurality of substrates in horizontal orientations, said load-lock chamber being accessible by said arm for transferring said substrates between said cassette and any of said processing chambers.

16. A vacuum processing system, comprising:
at least one individually vacuum pumpable processing chamber having a pedestal therein for supporting a substrate during processing therein;
an individually vacuum pumpable transfer chamber;
a selectively openable vacuum door separating said processing chamber from said transfer chamber;
a vertical lift mechanism disposed in said transfer chamber;
a first motor disposed in said chamber and coupled to said vertical lift mechanism to cause it to raise and lower;
a tracked mechanism supported on said vertical lift mechanism and having a paddle for supporting a substrate thereon and being extensible from a retracted position within said transfer chamber when said vacuum door is closed to an extended position extending through said vacuum door when it is open to transfer said substrate to and from said pedestal in said processing chamber; and
a second motor disposed in said chamber and coupled to said tracked mechanism to cause it to extend and retract.

17. The vacuum processing system of claim 16, wherein said tracked mechanism is a two-stage tracked mechanism coupled to said second motor.
